(19) United States
(12) Patent Application Publication
(10) Pub. No.: US 2018/0337334 A1
(43) Pub. Date: Nov. 22, 2018

(54) METHOD AND DEVICE FOR MANUFACTURING DEPOSITION MASK

(71) Applicant: Samsung Display Co., Ltd., Yongin-si (KR)

(72) Inventors: Jeongkuk KIM, Yongin-si (KR); Youngmin MOON, Yongin-si (KR); Sungsoon IM, Yongin-si (KR); Kyuhwan HWANG, Yongin-si (KR)

(21) Appl. No.: 15/724,082

(22) Filed: Oct. 3, 2017

(30) Foreign Application Priority Data
May 22, 2017 (KR) 10-2017-0062976

(51) Int. Cl. H01L 51/00; H01L 51/56; H01L 27/32; B23K 26/16; B23K 26/382; B23K 26/60

(52) U.S. Cl. CPC H01L 51/0011; H01L 51/56; B23K 26/60; B23K 26/16; B23K 26/382; H01L 27/3244

(57) ABSTRACT

A method of manufacturing a deposition mask includes forming a coating layer on a surface of a mask substrate, irradiating a laser beam onto the coating layer to form pattern openings in the mask substrate, and removing a residual film of the coating layer.

### CROSS-REFERENCE TO RELATED APPLICATION

This application claims priority to, and the benefit of, Korean Patent Application No. 10-2017-0062976, filed on May 22, 2017, in the Korean Intellectual Property Office, the disclosure of which is incorporated herein in its entirety by reference.

### BACKGROUND

### 1. Field

Aspects of the present disclosure relate to a method and a device for manufacturing a mask used for deposition.

### 2. Description of the Related Art

In general, an organic light-emitting diode (OLED) display, which is capable of realizing color by using a principle whereby light is generated when excitons (which are generated as holes and electrons injected from an anode and a cathode combine in an emission layer) change from an excited state to a ground state, has pixels in a stacked structure in which the emission layer is interposed between a pixel electrode serving as the anode and an opposite electrode serving as the cathode.

Each of the sub-pixels may be, for example, a red sub-pixel, a green sub-pixel, or a blue sub-pixel, and a desired color may be represented by a color combination of the three colored sub-pixels. That is, a structure in which an emission layer emitting light of any one of red, green, and blue colors is interposed between two electrodes for each sub-pixel, and color of one unit pixel (i.e., a sub-pixel) is displayed by an appropriate combination of red, green, and blue colored lights.

The electrodes and the emission layer of the OLED display may be formed by deposition. That is, a mask having pattern holes (i.e., pattern openings) with the same pattern as that of a thin-film layer to be formed is aligned on a substrate, and a raw material of a thin-film is deposited on the substrate through the pattern holes of the mask to form a thin-film of a desired pattern. The mask is often used in a form of a mask frame assembly together with a frame for supporting an end portion thereof, and the pattern holes may be formed by laser beam processing to irradiate a mask body with a laser beam to punch holes (i.e., openings).

However, dust may inevitably be generated when the pattern holes of the mask are punched with a laser beam, which may interfere with the processing of the pattern holes. That is, when the dust generated during the laser beam processing is accumulated on a surface of the mask body, the laser beam may not be sufficiently irradiated into the mask body at the portion where the dust is accumulated, so that an unprocessed hole, in which the hole is not completely punched, is likely to be generated. This may result in a bad mask that cannot be used for deposition, and the dust may significantly affect quality and productivity of the product. Therefore, a countermeasure for effectively solving such a problem is desired.

The above information disclosed in this Background section is only for enhancement of understanding of the background of the invention and therefore it may contain information that does not form the prior art.

### SUMMARY

Aspects of embodiments of the present disclosure are directed to methods and devices for manufacturing an improved deposition mask, which can reduce a risk of occurrence of unprocessed holes (i.e., unprocessed openings) due to dust during pattern hole processing (i.e., pattern opening processing) using a laser beam.

Additional aspects will be set forth in part in the description that follows and, in part, will be apparent from the description, or may be learned by practice of the presented example embodiments.

According to one or more example embodiments, there is provided a method of manufacturing a deposition mask, the method including: forming a coating layer on a surface of a mask substrate; irradiating a laser beam onto the coating layer to form pattern openings in the mask substrate; and removing a residual film of the coating layer.

In an embodiment, the mask substrate comprises an iron-nickel alloy.

In an embodiment, the coating layer includes an organic material having higher laser beam absorptivity than that of the mask substrate.

In an embodiment, the coating layer has a lower boiling point than that of the mask substrate.

In an embodiment, the coating layer includes at least one of polyimide or photoresist.

In an embodiment, the coating layer has a thickness of 5 μm to 40 μm.

In an embodiment, a wavelength of the laser beam is in a range of 400 nm to 600 nm.

In an embodiment, dust scattered during punching of the pattern openings is accumulated on the coating layer.

In an embodiment, the method further includes: extracting and discharging the scattered dust.

In an embodiment, the coating layer and the mask substrate are concurrently punched at a portion irradiated with the laser beam.

In an embodiment, the method further includes: removing the residual film of the coating layer by cleaning with an organic solvent.

According to one or more example embodiments, there is provided a device for manufacturing a deposition mask, the device including: a chuck configured to support a mask substrate; a coating depositor configured to form a coating layer on a surface of the mask substrate; a laser beam irradiator configured to irradiate a laser beam onto the coating layer to form pattern openings in the mask substrate; and a cleaner configured to clean and remove a residual film of the coating layer.

In an embodiment, the mask substrate includes an iron-nickel alloy.

In an embodiment, the coating layer includes an organic material having a higher laser beam absorptivity than that of the mask substrate.

In an embodiment, the coating layer has a lower boiling point than that of the mask substrate.

In an embodiment, the coating layer includes any one of polyimide and photoresist.

In an embodiment, the coating layer has a thickness of 5 μm to 40 μm.

In an embodiment, a wavelength of the laser beam is in a range of 400 nm to 600 nm.

In an embodiment, the device further includes: a suction apparatus configured to suck up and discharge dust scattered during punching of the pattern openings.

In an embodiment, the cleaner is configured to remove the residual film of the coating layer by cleaning with an organic solvent.

### BRIEF DESCRIPTION OF THE DRAWINGS

These and/or other aspects will become apparent and more readily appreciated from the following description of the example embodiments, taken in conjunction with the accompanying drawings in which:

FIG. 1 is a view of a deposition process using a deposition mask manufactured according to an example embodiment of the present disclosure;

FIG. 2 is a disassembled perspective view of a mask frame assembly including the deposition mask of FIG. 1;

FIG. 3 is a configuration diagram of a device for manufacturing a deposition mask, according to an example embodiment of the present disclosure;

FIGS. 4A-4D are cross-sectional views of a process of manufacturing a deposition mask, in sequence, according to an example embodiment of the present disclosure; and

FIG. 5 is a cross-sectional view of a detailed structure of a target substrate in FIG. 1.

### DETAILED DESCRIPTION

As the present disclosure allows for various suitable changes and numerous embodiments, embodiments will be illustrated in the drawings and described in detail in the written description. An effect and a characteristic of the present disclosure, and a method of accomplishing these will be apparent when referring to embodiments described with reference to the drawings. This present disclosure may, however, be embodied in many different forms and should not be construed as limited to the embodiments set forth herein.

Reference will now be made in detail to example embodiments, examples of which are illustrated in the accompanying drawings, wherein like reference numerals refer to like elements throughout, and repeated description thereof may be omitted.

Sizes of components in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

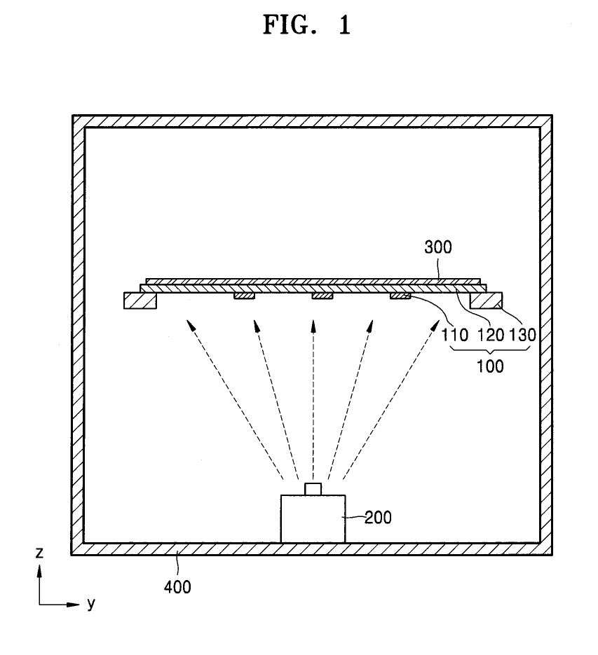

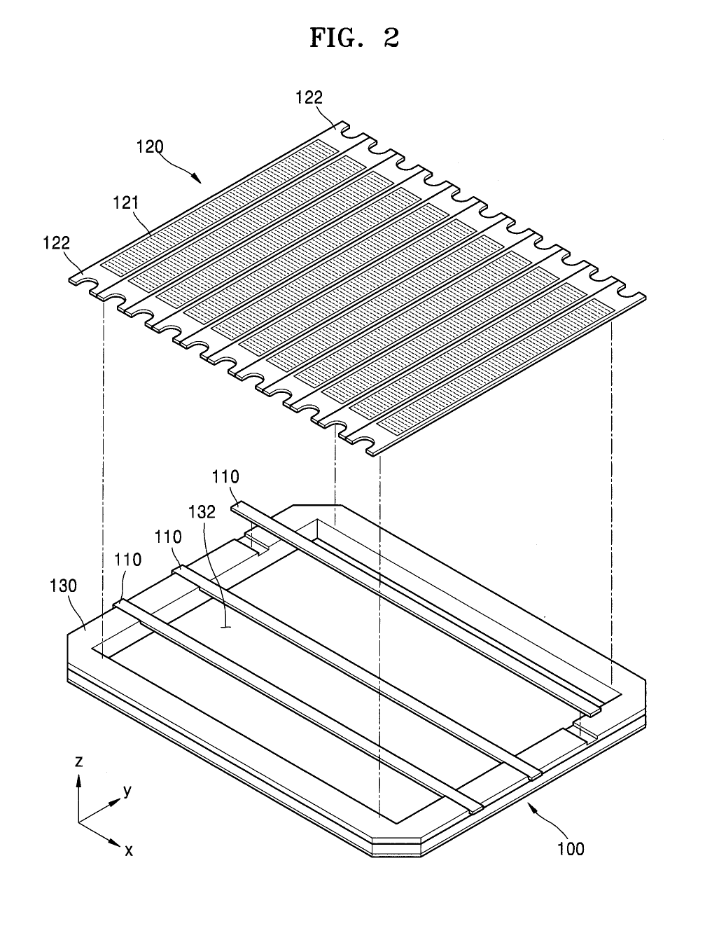

FIG. 1 is a schematic sectional view of a structure of a thin-film deposition device employing a deposition mask 120, according to an example embodiment of the present disclosure. FIG. 2 is a disassembled perspective view of a mask frame assembly 100 including the deposition mask 120 of FIG. 1.

As shown in FIG. 1, the thin-film deposition device includes the deposition mask 120 for forming a desired pattern on a target substrate 300, a deposition source 200 for ejecting a deposition gas toward the target substrate 300 in a chamber 400, and the like.

Accordingly, when the deposition source 200 ejects the deposition gas in the chamber 400, the deposition gas passes through pattern holes (i.e., pattern openings) 121 (see FIG. 2) of the deposition mask 120 and adheres to the target substrate 300, thereby forming a thin film of a predetermined pattern.

As shown in FIG. 2, the deposition mask 120 may be used with the mask frame assembly 100, which includes a frame 130 for supporting both ends of the deposition mask 120, and a long-side beam (or bar) 110 supported on the frame 130 to cross the deposition mask 120.

That is, the mask frame assembly 100 includes the frame 130, a plurality of long-side beams 110 having both ends fixed to the frame 130, and a plurality of deposition masks 120 perpendicular to the long-side beams 110 and having both ends fixed to the frame 130.

The frame 130 forms an outer frame of the mask frame assembly 100, and has a rectangular shape with an opening 132 formed at the center thereof. Both ends of the long-side beam 110 may be fixed by welding or any suitable fixing mechanism to opposing sides of the frame 130. Both ends of the deposition mask 120 may be fixed to a pair of sides of the frame 130 that cross (e.g., are perpendicular to) the sides of the frame 130 to which the long-side beam 110 is welded or is affixed.

The deposition mask 120 has elongated beam-shaped members and forms a plurality of pattern holes 121 located in the opening 132. Both ends of the deposition mask 120 may be welded or affixed to the frame 130 as described above. Reference numeral 122 denotes an interlocking member having teeth and grooves. When the deposition mask 120 is welded or affixed to the frame 130, the interlocking member 122 is held and extended in a longitudinal direction and is removed by cutting after welding/fixing. The deposition mask 120 may be one large member, but in this case, a drooping phenomenon due to its own weight may be increased. To prevent or reduce drooping, the deposition mask 120 may be divided into a plurality of beams as shown in FIG. 2. Invar® (a registered trademark of Aperam Imphy Alloys), which is an iron-nickel alloy, may be used as a material of the deposition mask 120.

The pattern holes 121 are holes (i.e., openings) through which deposited vapor passes during a deposition process. The deposited vapor passing through the pattern holes 121 adheres to the target substrate 300 (see FIG. 1) to form a thin-film layer.

Here, an area in which the pattern holes 121 are formed is not divided into cells of a predetermined size but forms a contiguous piece. The long-side beam 110 divides the set of pattern holes 121 into cell units (e.g., cells). That is, the deposition mask 120 and the long-side beam 110 are installed on the frame 130 so as to be in close contact with each other while perpendicularly crossing each other as shown in FIG. 2, so that the long-side beam crosses the area of each of the pattern holes 121 of the deposition mask 120 and divides the area into cell units. That is, the long-side beam 110 draws boundary lines between the cell units.

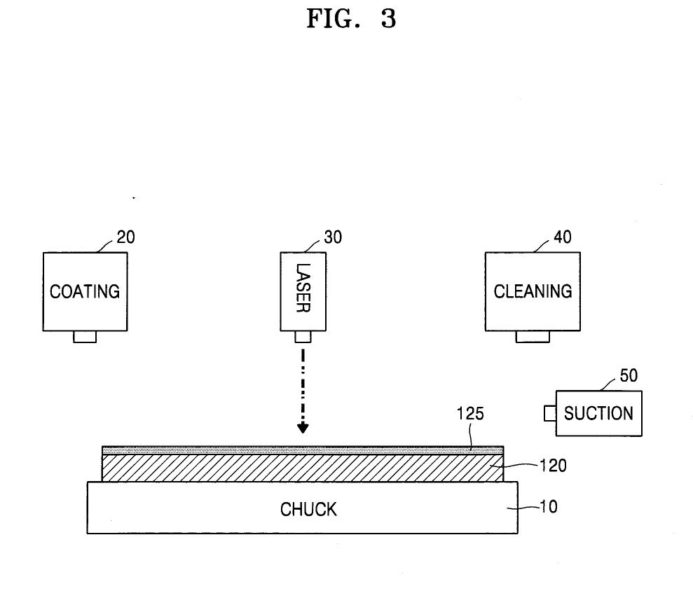

The pattern holes 121 of the deposition mask 120 may be manufactured by a device as shown in FIG. 3. FIG. 3 illustrates a schematic configuration, but the configuration is not limited to the arrangement as illustrated. That is, an arrangement of a chuck 10, a coating unit (e.g., a coating depositor) 20, a laser beam irradiator 30, a cleaning unit (e.g., a cleaner) 40, a suction unit (a suction apparatus) 50, and/or the like may be variously changed in a suitable manner as long as the functions described below can be performed.

First, the chuck 10, on which a mask substrate 120 including the pattern holes 121 is mounted, supports the mask substrate 120 during processing. Here, the same reference numeral as the deposition mask 120 is used to refer to the mask substrate 120, because the mask substrate 120 becomes the deposition mask 120 after (or immediately after) the pattern holes 121 are formed.

The coating unit 20 forms a coating layer 125 of an organic material on an upper surface of the mask substrate 120, which is opposite to a surface facing the chuck 10. A reason for forming the coating layer 125 in this way is to solve a problem that may be caused by dust during laser beam processing, which is a concern related to a generation of unprocessed holes (i.e., unprocessed openings) due to dust, as mentioned above. The detailed principle will be described further below with respect to a manufacturing process.

The laser beam irradiator 30 emits a laser beam directly toward the mask substrate 120 to punch (e.g., cut or drill) the pattern holes 121 with energy of the laser beam. Here, the laser beam is irradiated onto the coating layer 125 as described above, and the portion irradiated with the laser beam on the coating layer 125 is also punched (e.g., cut or drilled) together with the mask substrate 120. Because the laser beam passes through the coating layer 125, the coating layer 125 uses an organic material having laser beam absorptivity higher than that of the mask substrate 120 and a boiling point lower than that of the mask substrate 120. Invar® having a boiling point of 2,732° C. is mainly used as the mask substrate 120 and a laser beam having a wavelength range of 400 nm to 600 nm is used as a laser beam of the laser beam irradiator 30. Thus, in some embodiments, the coating layer 125 uses an organic material, such as polyimide or photoresist, which has higher laser beam absorptivity and a lower boiling point than those of invar® in the wavelength range of the laser beam.

Reference numeral 50 denotes a suction unit for extracting (e.g., collecting or sucking up) and discharging dust during processing of the pattern holes 121 by the laser beam irradiator 30. Reference numeral 40 denotes a cleaning unit for removing a residual film of the coating layer 125 with an organic solvent after the processing of the pattern holes 121 by the laser beam irradiator 30 is completed.

A detailed process of manufacturing the deposition mask 120 using a device for manufacturing a deposition mask will be described below, and an example of the target substrate 300 that can be deposited with the deposition mask 120 will be briefly described first.

The deposition mask 120 may be used for various suitable thin-film depositions, for example, to form an emission layer pattern of an organic light-emitting diode (OLED) display.

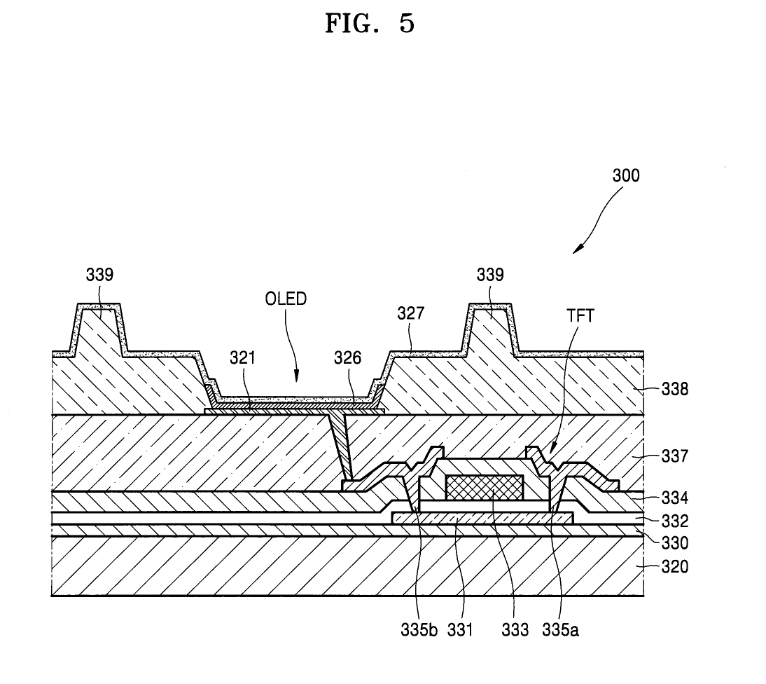

FIG. 5 is a view of a structure of the OLED display as an example of the target substrate 300 on which a thin film can be deposited using the deposition mask 120 of the present disclosure.

Referring to FIG. 5, a buffer layer 330 is formed on a base plate 320, and a thin-film transistor TFT is provided on the buffer layer 330.

The thin-film transistor TFT includes an active layer 331, a gate-insulating layer 332 formed so as to cover the active layer 331, and a gate electrode 333 above the gate-insulating layer 332.

An interlayer-insulating layer 334 is formed to cover the gate electrode 333, and a source electrode 335a and a drain electrode 335b are formed on the interlayer-insulating layer 334.

The source electrode 335a and the drain electrode 335b are respectively in contact with a source region and a drain region of the active layer 331 via contact openings (e.g., contact holes) formed in the gate-insulating layer 332 and the interlayer-insulating layer 334.

In addition, a pixel electrode 321 of an organic light-emitting diode OLED is connected to the drain electrode 335b. The pixel electrode 321 is formed on a planarization layer 337 and has a pixel-defining layer 333 for partitioning a sub-pixel area on the pixel electrode 321. Reference numeral 339 denotes a spacer for preventing or reducing damage to members on the side of the substrate 300 due to a contact of the mask frame assembly 100 by maintaining a gap with the mask frame assembly 100 during deposition, and the spacer 339 may be formed in a shape in which a portion of a pixel-defining layer 338 is protruded. An emission layer 326 of the organic light-emitting diode OLED is formed in an opening of the pixel-defining layer 338 and an opposite electrode 327 is deposited thereon. That is, the opening surrounded by the pixel-defining layer 338 is an area of one sub-pixel, such as a red pixel R, a green pixel G, and a blue pixel B, and the emission layer 326 of the corresponding color is formed therein.

Therefore, for example, when the deposition mask 120 is prepared so that the pattern holes 121 correspond to the emission layer 326, the emission layer 326 having a desired pattern may be formed through the deposition process as described above with reference to FIG. 1. The cell units may correspond to a display area of an OLED display.

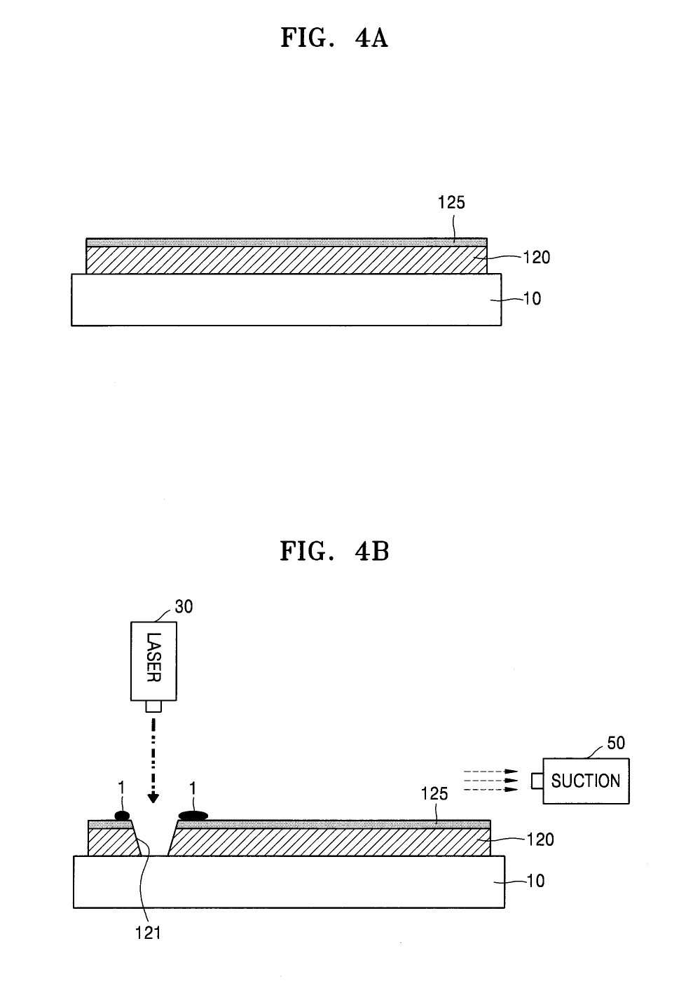

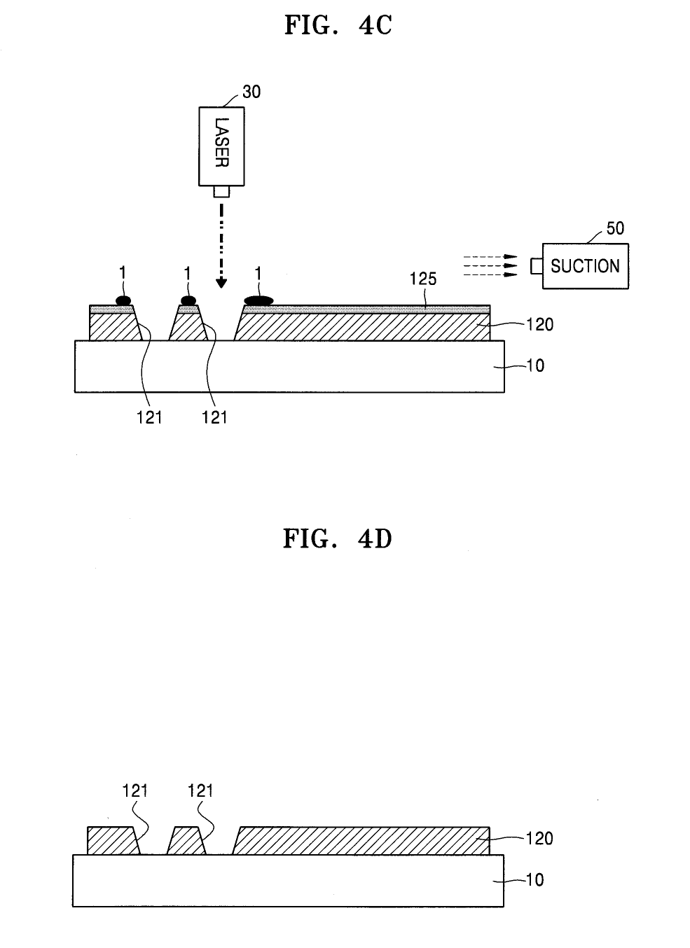

Hereinafter, a process of forming the pattern holes 121 of the deposition mask 120 capable of forming such an OLED display will be described further with reference to FIGS. 4A to 4D.

First, as illustrated in FIG. 4A, the mask substrate 120 is placed on the chuck 10 and the coating unit 20 is operated to form the coating layer 125 on an upper surface of the mask substrate 120 with a thickness of about 5 μm to about 40 μm. As a material of the coating layer 125, an organic material having higher laser beam absorptivity and a lower boiling point than those of the mask substrate 120 made of invar©, such as polyimide and photoresist, is used.

Then, as shown in FIG. 4B, the laser beam irradiator 30 is operated to emit a laser beam having a wavelength range of 400 nm to 600 nm through the coating layer 125 to a desired position, thereby punching (e.g., cutting or drilling) the pattern holes 121. Here, holes, that is, the pattern holes 121, are formed in portions irradiated with a laser beam while the coating layer 125 and the mask substrate 120 are removed together, and dust 1 scattered while being removed from the pattern holes 121 is accumulated again in the vicinity of the formed pattern holes 121. Although the suction unit 50 is operated to extract (e.g., collect or suck up) and discharge the scattered dust 1, some of the dust 1 may remain and accumulate around the pattern hole 121.

In this state, if the pattern hole 121 is punched again at the adjacent point as shown in FIG. 4C, the dust 1 accumulated in the vicinity as described above may prevent or substantially prevent laser beam irradiation, that is, prevent or substantially prevent laser beam energy from reaching the mask substrate 120 sufficiently. However, because the dust 1 is on the coating layer 125 having very high laser beam absorptivity, the dust 1 may be immediately removed together with the coating layer 125 during laser beam irradiation. That is, as described above, because the coating layer 125 itself has high laser beam absorptivity and a low boiling point, when a laser beam is irradiated onto the coating layer 125, the irradiated portion absorbs the laser beam energy and immediately disappears as it sublimates. Accordingly, the dust 1 on the coating layer 125 is also removed naturally. Because the coating layer 125 and the dust 1 are removed (e.g., completely removed) and the exposed mask substrate 120 is irradiated with a laser beam, it is possible to perform accurate laser beam processing without an influence of the dust 1.

Thereafter, when the residual film of the coating layer 125 is removed by the cleaning unit 40, the deposition mask 120 having clean pattern holes 121, as shown in FIG. 4D, is obtained. Here, for convenience of illustration, only two pattern holes 121 are illustrated. However, a plurality of pattern holes 121 may be formed as shown in FIG. 2, and the coating layer 125 is immediately removed together with the dust 1 at every position irradiated with a laser beam, and then the pattern holes 121 are punched.

Therefore, when the pattern holes 121 of the deposition mask 120 are formed in this manner, a problem of laser beam energy not sufficiently reaching the mask substrate 120 due to the dust 1 and unprocessed holes being generated may be sufficiently solved.

The present example embodiment shows a case where the deposition mask 120 divided into a plurality of beams is formed. However, the present example embodiment may be applied to an integrated mask covering the entire opening 132 of the frame 130 with one member, or a mask in which the pattern holes 121 are partitioned in cell units in the deposition mask 120 without the long-side beam 110. That is, a device and a method of manufacturing a deposition mask according to the present example embodiment may be applied regardless of the type of mask when the pattern holes 121 are formed by directly irradiating a laser beam.

Therefore, according to the device and the method of manufacturing a deposition mask as described above, dust can be effectively removed together with a coating layer when pattern holes are formed by a laser beam, so that a risk of occurrence of unprocessed holes due to dust may be reduced. As a result, it is possible to ensure stable (e.g., consistent and high) quality of products.

It will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

The thin-film deposition device and/or any other relevant devices or components, such as the deposition source, the laser, the coating depositor, the cleaner, and the suction apparatus, according to embodiments of the present invention described herein may be implemented utilizing any suitable hardware, firmware (e.g. an application-specific integrated circuit), software, or a suitable combination of software, firmware, and hardware. For example, the various components of the thin-film deposition device may be formed on one integrated circuit (IC) chip or on separate IC chips. Further, the various components of the thin-film deposition device may be implemented on a flexible printed circuit film, a tape carrier package (TCP), a printed circuit board (PCB), or formed on a same substrate. Further, the various components of the thin-film deposition device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

It should be understood that example embodiments described herein should be considered in a descriptive sense and not for purposes of limitation. Descriptions of features or aspects within each example embodiment should typically be considered as available for other similar features or aspects in other example embodiments.

While one or more example embodiments have been described with reference to the figures, it will be understood by those of ordinary skill in the art that various suitable changes in form and details may be made therein without departing from the spirit and scope as defined by the following claims and equivalents thereof.

What is claimed is:

1. A method of manufacturing a deposition mask, the method comprising:
forming a coating layer on a surface of a mask substrate;
irradiating a laser beam onto the coating layer to form pattern openings in the mask substrate; and
removing a residual film of the coating layer.

2. The method of claim 1, wherein the mask substrate comprises an iron-nickel alloy.

3. The method of claim 1, wherein the coating layer comprises an organic material having higher laser beam absorptivity than that of the mask substrate.

4. The method of claim 3, wherein the coating layer has a lower boiling point than that of the mask substrate.

5. The method of claim 3, wherein the coating layer comprises at least one of polyimide or photoresist.

6. The method of claim 3, wherein the coating layer has a thickness of 5 μm to 40 μm.

7. The method of claim 1, wherein a wavelength of the laser beam is in a range of 400 nm to 600 nm.

8. The method of claim 1, wherein dust scattered during punching of the pattern openings is accumulated on the coating layer.

9. The method of claim 8, further comprising:
extracting and discharging the scattered dust.

10. The method of claim 1, wherein the coating layer and the mask substrate are concurrently punched at a portion irradiated with the laser beam.

11. The method of claim 1, further comprising:
removing the residual film of the coating layer by cleaning with an organic solvent.

12. A device for manufacturing a deposition mask, the device comprising:
a chuck configured to support a mask substrate;
a coating depositor configured to form a coating layer on a surface of the mask substrate;
a laser beam irradiator configured to irradiate a laser beam onto the coating layer to form pattern openings in the mask substrate; and
a cleaner configured to clean and remove a residual film of the coating layer.

13. The device of claim 12, wherein the mask substrate comprises an iron-nickel alloy.

14. The device of claim 12, wherein the coating layer comprises an organic material having a higher laser beam absorptivity than that of the mask substrate.

15. The device of claim 14, wherein the coating layer has a lower boiling point than that of the mask substrate.

16. The device of claim 14, wherein the coating layer comprises any one of polyimide and photoresist.

17. The device of claim 14, wherein the coating layer has a thickness of 5 μm to 40 μm.

18. The device of claim 12, wherein a wavelength of the laser beam is in a range of 400 nm to 600 nm.

19. The device of claim 12, further comprising:
a suction apparatus configured to suck up and discharge dust scattered during punching of the pattern openings.

20. The device of claim 12, wherein the cleaner is configured to remove the residual film of the coating layer by cleaning with an organic solvent.
